(19) United States
(12) Patent Application Publication
(10) Pub. No.: US 2014/0132343 A1
(43) Pub. Date: May 15, 2014

(54) POWER AMPLIFIER BASED ON DOHERTY POWER AMPLIFIER

(71) Applicants: Paolo Colantonio, Roma (IT); Franco Giannini, Roma (IT); Rocco Giofre, San Cesareo, (RM) (IT); Luca Piazzon, Roma (IT)

(72) Inventors: Paolo Colantonio, Roma (IT); Franco Giannini, Roma (IT); Rocco Giofre, San Cesareo, (RM) (IT); Luca Piazzon, Roma (IT)

(73) Assignee: Telefonaktiebolaget L M Ericsson (PUBL), Stockholm (SE)

(21) Appl. No.: 14/128,559

(22) PCT Filed: Jun. 20, 2011
(86) PCT No.: PCT/EP2011/060215

§ 371 Date: Dec. 20, 2013

(51) Int. Cl. H03F 1/02; H03F 3/68; H03F 3/20

(52) U.S. Cl. CPC H03F 1/02; H03F 3/20; H03F 3/68
USPC 330/124 R

(57) ABSTRACT

The invention provides a power amplifier (300) arranged to receive an input power signal (Pin) at an input port of a three port Input Power Splitter, IPS. The IPS is arranged to deliver a main input power signal (P1) to a main amplifier branch and an auxiliary input power signal (P2) to an auxiliary amplifier branch. The power amplifier (300) is arranged to deliver an output power signal (Pout) to a common node. A Phase Compensation Network, PCN, is arranged in the main amplifier branch. A Nonlinear Driver Amplifier, NDA, is arranged in the auxiliary amplifier branch. The NDA is arranged to increase the gain in the auxiliary amplifier branch. The invention also provides a corresponding method and a node in a wireless communication system comprising the power amplifier.

### TECHNICAL FIELD

The present invention relates to the field of microwave power amplifiers for use in electronic systems, e.g. in radio base stations (RBS) used in wireless communication systems.

### BACKGROUND

The Doherty Power Amplifiers (DPA) architecture was introduced by W. H. Doherty in 1936, with the aim to realize power stages with almost constant and higher efficiency behaviour for a well determined range of output power. A main application for Doherty amplifiers is communication systems.

The standard topology of the DPA is shown in FIG. 1, where input and output ports as well as input and output ends of the DPA and of all components of the DPA, are all referred to a reference point or reference plane having a reference potential, e.g. a ground plane or a ground point. This is equivalent to all components having an additional input and output port, or input and output end, connected to the reference point or the reference plane, e.g. the ground point or the ground plane. This reference point or reference plane is henceforth called a ground, in FIG. 1 the ground 108. The DPA 100 is arranged to receive an input power signal Pin at an input port 120 of a three port Input Power Splitter, IPS, 101, comprising a first 121 and a second 122 output port. The IPS is arranged to deliver a main input power signal P1 at the first output port 121 to an input end 123 of a main amplifier branch 102 comprising a main amplifier 103 coupled in series with an Impedance Inverter Network, IIN 104, having an IIN input port 128 connected to an output end 125 of the main amplifier and an IIN output port 129 connected to a common node 107. The IPS is further arranged to deliver an auxiliary input power signal P2 at the second output port 122 to an input end 124 of an auxiliary amplifier branch 105 comprising an auxiliary amplifier 106. The output end 125 of the main amplifier is connected to an output end of the auxiliary amplifier branch 105 via the IIN 104, the output end of the auxiliary amplifier branch defining the common node 107. A Phase Compensation Network (PCN) 109 is arranged in the auxiliary amplifier branch between the second output port 122 and an input end 126 of the auxiliary amplifier 106. The power amplifier 100 is arranged to deliver an output power signal Pout to a load Z_{L} to be connected to the DPA, the load having a first end and a second end, the first end being connected to the common node 107 and the second end to the ground 108.

The relation between the main input power signal P1 and the auxiliary input power signal P2 at the output ports of the IPS for the above described DPA is much less than one, i.e. the auxiliary input power signal P2 is much greater than the main input power signal P1 at the output ports of the IPS because the auxiliary amplifier branch is biased in class C and the main amplifier branch in class AB which results in a lower gain in the auxiliary amplifier branch which means that the auxiliary input power signal P2 has to be much greater than the main input power signal P1 at the output ports of the IPS in order for the power output of the branches to be balanced, i.e. to be approximately equal at saturation of the DPA, i.e. when the DPA is delivering its maximum output power signal Pout.

The Doherty amplifier is well known to the skilled person and therefore not further discussed here. Basics of the DPA can e.g. be found in “The Doherty Power Amplifier,” chapter 6 pp. 107-132, by P. Colantonio, F. Giannini, R. Giofrè, L. Piazzon, in the book “Advanced Microwave Circuits and Systems,” Ed. Vitaliy Zhurbenko, April 2010 (ISBN: 978-953-307-087-2).

The impedance inverter network IIN is typically implemented through a lambda-quarter transmission line (i.e. a transmission line with 90° of electrical length at the centre frequency of the operating bandwidth of the DPA).

The phase compensation network PCN is typically realized by the same structure as used for the IIN, and arranged in the auxiliary amplifier branch.

The input power splitter IPS, is required to split the input power signal Pin towards the main and auxiliary amplifiers with a proper power splitting factorization. For low levels of the input power signal Pin only the main amplifier is operating, while the auxiliary amplifier is properly kept off. When the input power signal Pin is increased and the main amplifier is reaching its saturation, the auxiliary amplifier is turned on increasing the current flowing into the load Z_{L} and consequently increasing the voltage at the common node 107. The resulting higher impedance seen from the IIN output port 129 is transformed into a smaller impedance, in the typical case with a lambda-quarter IIN into a smaller impedance sometimes called an inverted impedance, at the main amplifier output end 125, thus allowing the main amplifier to further increase the output power signal Pout delivered, up to the saturation of both amplifiers.

The operating region, when both the main and auxiliary amplifiers are in operation, is usually referred as the Doherty power region, and it is properly controlled by suitable design parameters, in order to maintain almost constant and high amplifier efficiency for a required output back-off (OBO) region. The OBO is the amount of back-off from the maximum power output of the DPA needed for the required amplitude modulation of the output power signal Pout from the DPA. The DPA efficiency is defined as the AC power of the output power signal Pout over the load Z_{L} in relation to the required DC (Direct Current) power supplied to the DPA. Power Added Efficiency, PAE, is defined as the difference between the AC power of the output power signal Pout over the load Z_{L} and the AC power delivered to the DPA via the input power signal Pin divided with the DC power supplied to the DPA. The terms OBO, efficiency and PAE are also valid for any type of power amplifier. The DC power is required for operation of the amplifiers of the DPA which is well known to the skilled person.

In the original DPA both the main and the auxiliary amplifiers were based on class B or AB biasing condition, while the proper turning on condition of the auxiliary amplifier was assured by suitable switch control circuitry. Class A, B, AB and C amplifiers are well known to the skilled person and therefore not further discussed here.

In actual implementations, the main amplifier is often operated in class AB bias condition, while the auxiliary amplifier is operating in class C, with the aim to be kept off for low levels of the input power signal Pin, thus avoiding switching elements and losses associated with switching.

The standard DPA topology, while assuring a higher efficiency for a defined OBO than conventional solutions, suffers from a great gain decrease compared to conventional solutions such as a classical combination of two identical amplifiers realized with the same technology as for the main and the auxiliary amplifiers. Such an example of prior art, a combination of two identical amplifiers, is shown in FIG. 2. Here the input and output ports as well as input and output ends of the combined power amplifier 200 and of all components of the combined power amplifier, are all referred to a reference point or reference plane having a reference potential, e.g. a ground plane or a ground point. This is equivalent to all components having an additional input and output port, or input and output end, connected to the reference point or the reference plane, e.g. the ground point or the ground plane, in FIG. 2 the ground 208. The combined power amplifier 200 is arranged to receive an input power signal Pin at an input port of a three port 3 dB Power Splitter, 201, comprising a first and a second output port. The 3 dB Power Splitter is arranged to deliver a first input power signal P1 at the first output port to an input end of a first amplifier 202 and a second input power signal P2 at the second output port to an input end of a second amplifier 203. Each output end of the amplifiers is connected to different input ports of a three port 3 dB power combiner 204 having two input ports and one output port. The output port of the 3 dB power combiner delivers an output power signal Pout to a load Z_{L} to be connected to the combined power amplifier, the load having a first end and a second end, the first end being connected to the output port of the 3 dB power combiner and the second end to the ground 208. A drawback with this standard combined power amplifier is a low efficiency, when operating in OBO condition, compared to the DPA solution. The relation between the first input power signal P1 and the second input power signal P2 at the output ports of the 3 dB Power splitter is equal to 1.

This relatively low gain of the DPA is mainly related to two causes:
the uneven splitting factor required for the IPS as described in association with FIG. 1, unbalanced towards the auxiliary amplifier, i.e. the auxiliary input power signal P2 is much greater than the main input power signal P1 at the output ports of the IPS
and the class C bias condition of the auxiliary power amplifier, resulting in a lower gain capability as compared to a class AB bias condition.

There is thus a need for an improved power amplifier with a high gain and simultaneously a high efficiency compared to prior art solutions.

### SUMMARY

The object of the invention is to reduce at least some of the mentioned deficiencies with the prior art solutions and to provide:
a power amplifier
a method for power amplification
   to solve the problem to achieve a power amplifier and method for power amplification with high gain and simultaneously a high efficiency.

The object is achieved by a power amplifier arranged to receive an input power signal Pin at an input port of a three port Input Power Splitter, IPS, comprising also a first and a second output port. The IPS is arranged to deliver a main input power signal P1 at the first output port to an input end of a main amplifier branch comprising a main amplifier coupled in series with an Impedance Inverter Network, IIN, having an IIN input port and an IIN output port. The IPS is further arranged to deliver an auxiliary input power signal P2 at the second output port to an input end of an auxiliary amplifier branch comprising an auxiliary amplifier. An output end of the main amplifier is connected to an output end of the auxiliary amplifier branch via the IIN. The output end of the auxiliary amplifier branch defines a common node. The power amplifier is arranged to deliver an output power signal Pout to the common node wherein the power amplifier is arranged to operate within at least one frequency range, each frequency range defining a bandwidth with a centre frequency and wherein a Phase Compensation Network, PCN, is arranged in the main amplifier branch between the first output port of the IPS and an input end of the main amplifier. The output end of the main amplifier is connected to the IIN input port, the IIN output port being connected to the common node and wherein further a Nonlinear Driver Amplifier, NDA, is arranged in the auxiliary amplifier branch between the second output port of the IPS and an input end of the auxiliary amplifier. The output end of the auxiliary amplifier is connected to the common node. The PCN is arranged to adjust the phase of the main input power signal P1 in the main amplifier branch to be in phase with the auxiliary input power signal P2 in the auxiliary amplifier branch at the common node. The NDA is arranged to increase the gain in the auxiliary amplifier branch.

The object is further achieved by a method for power amplification where an input port of a three port Input Power Splitter, IPS, receives an input power signal Pin. The IPS also has a first and a second output port. The IPS delivers a main input power signal P1 at the first output port to an input end of a main amplifier branch having a main amplifier coupled in series with an Impedance Inverter Network, IIN, having an IIN input port and an IIN output port. The IPS further delivers an auxiliary input power signal P2 at the second output port to an input end of an auxiliary amplifier branch with an auxiliary amplifier. An output end of the main amplifier is connected to an output end of the auxiliary amplifier branch via the IIN. The output end of the auxiliary amplifier branch defines a common node. The power amplifier delivers an output power signal Pout to the common node wherein the power amplifier is operating within at least one frequency range, each frequency range defining a bandwidth with a centre frequency and wherein a Phase Compensation Network, PCN, is inserted in the main amplifier branch between the first output port of the IPS and an input end of the main amplifier. The output end of the main amplifier is connected to the IIN input port, the IIN output port being connected to the common node and wherein further a Nonlinear Driver Amplifier, NDA, is inserted in the auxiliary amplifier branch between the second output port of the IPS and an input end of the auxiliary amplifier. The output end of the auxiliary amplifier is connected to the common node. The PCN adjusts the phase of the main input power signal P1 in the main amplifier branch to be in phase with the auxiliary input power signal P2 in the auxiliary amplifier branch at the common node. The NDA increases the gain in the auxiliary amplifier branch.

The input and output ports, as well as the input and output ends, of the power amplifier and of all components of the power amplifier, are all referred to a reference point or a reference plane having a reference potential, e.g. a ground plane or a ground point. This is equivalent to all components having an additional input and output port, or input and output end, connected to the reference point or reference plane, e.g. the ground point or the ground plane. This reference point or reference plane is henceforth called a ground.

The invention also provides a node in a wireless communication system, the node comprising a power amplifier according to any one of claims 1-10.

Additional advantages are achieved by implementing one or several of the features of the dependent claims.

### BRIEF DESCRIPTION OF THE DRAWINGS

FIG. 1 schematically shows the topology of the standard Doherty Power Amplifier.

FIG. 2 schematically shows the topology of a standard combination of two power amplifiers.

FIG. 3 schematically shows the basic topology of the invention.

FIG. 4 schematically shows the topology of an example of the invention with a load.

FIG. 5 schematically shows a general impedance inverter network (IIN).

FIG. 6 schematically shows a first example of an impedance inverter network (IIN).

FIG. 7a schematically shows a second example of an impedance inverter network (IIN).

FIG. 7b schematically shows a third example of an impedance inverter network (IIN).

FIGS. 8a and 8b shows in diagrams an example of performance behaviour of the power amplifier of the invention and a standard DPA.

FIG. 9 schematically shows a block diagram of an example of the method of the invention.

### DETAILED DESCRIPTION

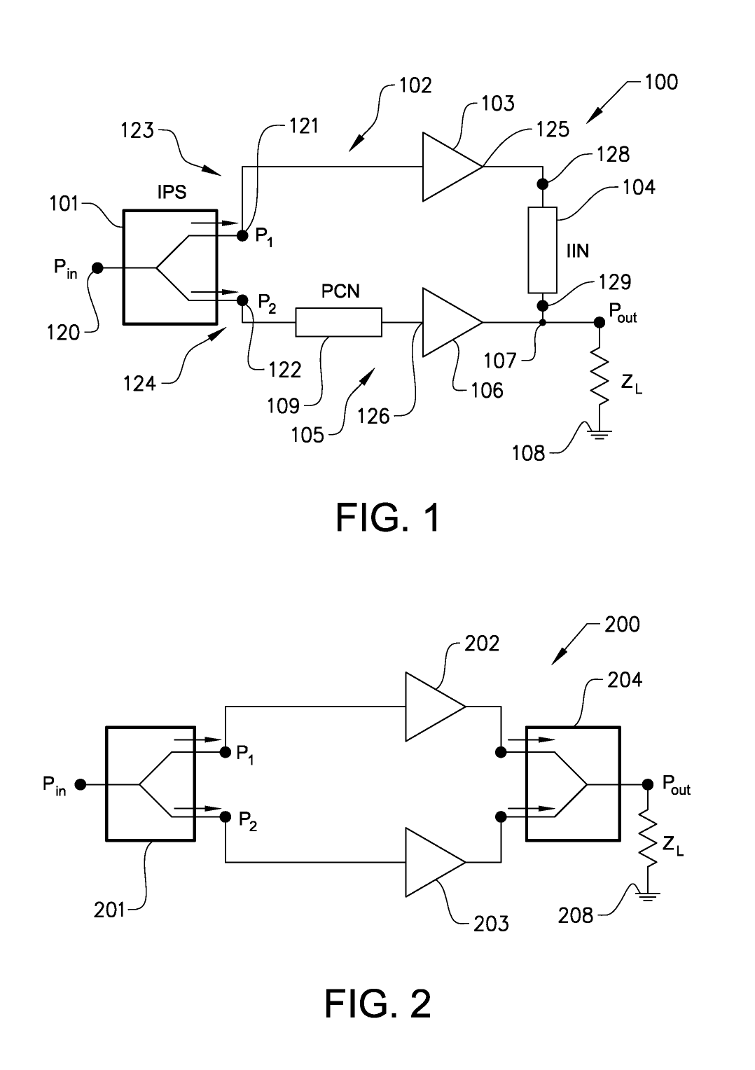

The invention will now be described with reference to the enclosed drawings, FIGS. 3-9. FIGS. 1 and 2 have been described in association with the Background part.

The input and output ports, as well as the input and output ends, of the power amplifier and of all components of the power amplifier are all referred to a reference point or a reference plane having a reference potential, e.g. a ground plane or a ground point. This is equivalent to all components having an additional input and output port, or input and output end, connected to the reference point or reference plane, e.g. the ground point or the ground plane. This reference point or reference plane is henceforth, as mentioned above, called a ground.

The OBO is the amount of back-off from the maximum power output of the power amplifier needed for the required amplitude modulation of the output power signal Pout from the power amplifier. The power amplifier efficiency is defined as the AC power of the output power signal Pout over the load Z_{L} in relation to the required DC power supplied to the power amplifier. Power Added Efficiency, PAE, is defined as the difference between the AC power of the output power signal Pout over the load Z_{L} and the AC power delivered to the power amplifier via the input power signal Pin divided with the DC power supplied to the power amplifier. The DC power is required for operation of the active components of the power amplifier, as e.g. different amplifiers (see FIG. 3), which is well known to the skilled person.

A basic topology of the new power amplifier of the invention is shown in FIG. 3, where the input and output ports, as well as the input and output ends, of the power amplifier and of all components of the power amplifier are all referred to the ground 308. This topology represents an evolution of the standard DPA topology, by the adoption of a third amplifier, namely a Nonlinear Driver Amplifier, NDA, which is arranged in the auxiliary amplifier branch and, in particular, at the input of the auxiliary amplifier, working as a non linear driver stage. The PCN, required in the auxiliary amplifier branch of the DPA in the topology of FIG. 1, is not required in the auxiliary amplifier branch in the topology of this new power amplifier. However, a PCN, in this example realized by means of an IIN, is arranged at the input of the main amplifier.

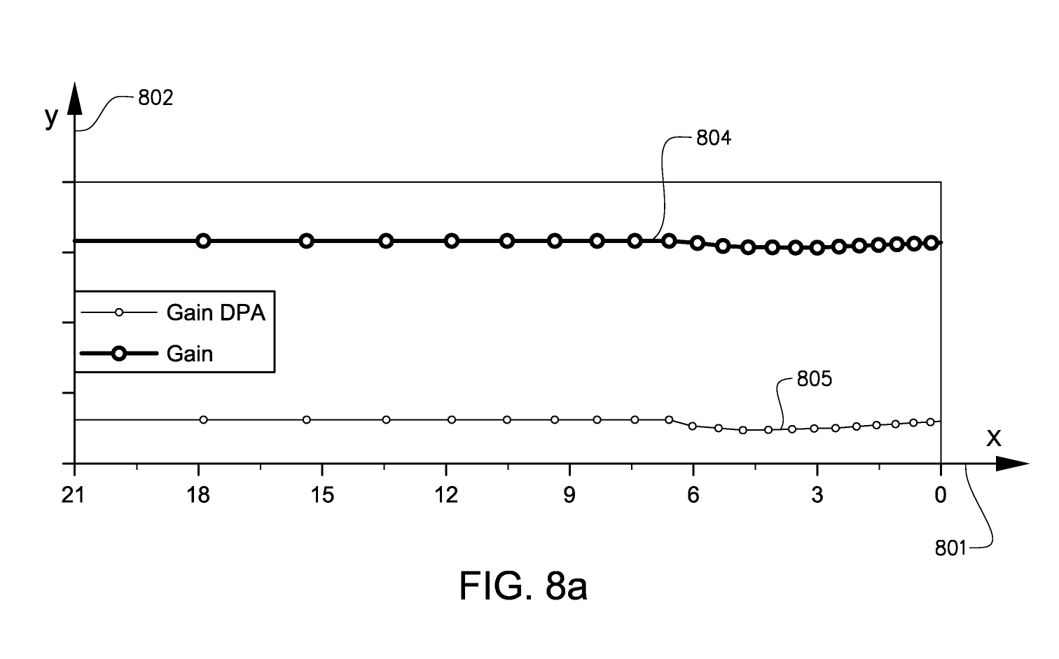

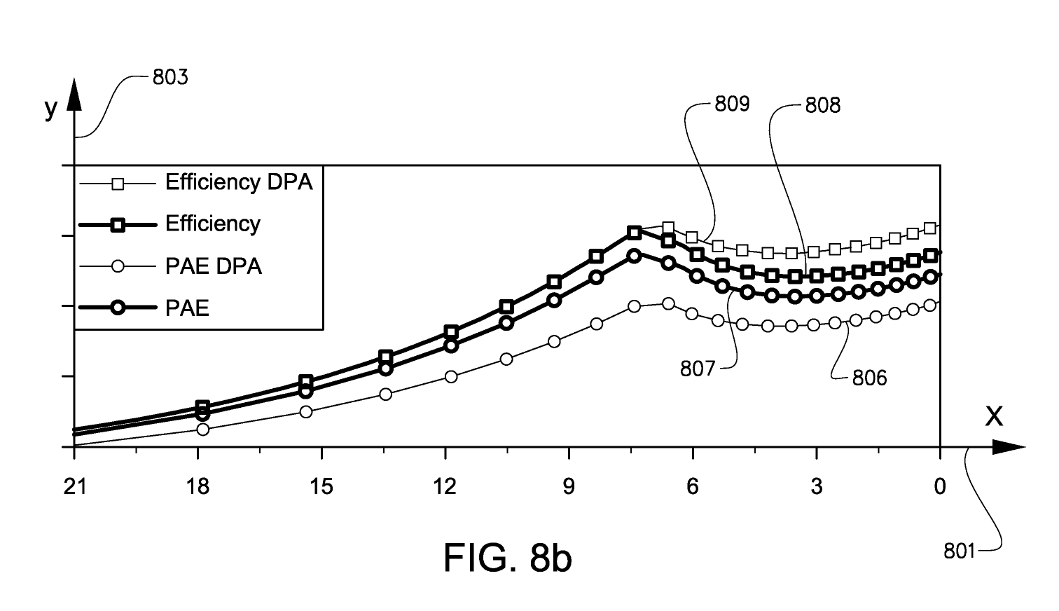

In terms of performance, the new power amplifier drastically increases the gain with about 3-6 dB, depending on the adopted technology, compared to the standard DPA approach, mainly for the following reasons:
In the proposed topology, the NDA increases the gain of the auxiliary amplifier branch. Consequently, the uneven splitting factor of the IPS can be inverted, i.e. unbalancing the power splitting toward the main amplifier, i.e. the main input power signal P1 is greater than the auxiliary input power signal P2 at the output ports of the IPS, thus allowing to reach a gain level similar to the one obtainable with a simple combination of two amplifiers as shown in FIG. 2.
By properly selecting the bias point of the NDA, in order to obtain the switching-on condition of the auxiliary amplifier branch, the auxiliary amplifier bias point can be shifted towards a class B bias condition, thus further increasing the gain of the auxiliary amplifier branch.
Simultaneously, the overall structure efficiency behaviour of the new power amplifier is not significantly affected compared to the standard DPA, as will be illustrated in FIGS. 8a and 8b. FIGS. 8a and 8b show an example of performance behaviour of the new power amplifier and a standard DPA, in terms of gain, efficiency and PAE.

The basic topology of the new power amplifier based on the DPA is shown in FIG. 3. The power amplifier 300 is arranged to receive an input power signal Pin at an input port 320 of a three port Input Power Splitter, IPS, 301, comprising also a first 321 and a second 322 output port. The IPS is arranged to deliver a main input power signal P1 at the first output port 321 to an input end 323 of a main amplifier branch 302 comprising a main amplifier 303 coupled in series with an Impedance Inverter Network, IIN 304, having an IIN input port 328 and an IIN output port 329. The IPS is further arranged to deliver an auxiliary input power signal P2 at the second output port 322 to an input end 324 of an auxiliary amplifier branch 305 comprising an auxiliary amplifier 306. An output end 325 of the main amplifier 303 is connected to an output end of the auxiliary amplifier branch 305 via the IIN 304, the output end of the auxiliary amplifier branch defining a common node 307. The power amplifier 300 is arranged to deliver an output power signal Pout to the common node 307.

The power amplifier 300 is arranged to deliver the output power signal Pout to a load Z_{L} connected to the power amplifier and having a first end and a second end, the first end being connected to the common node 307 and the second end to a ground 308. For practical realizations the value of Z_{L} should be real in order to maximize the output power signal Pout.

The invention is based on that a Nonlinear Driver Amplifier, NDA, 309 is arranged in the auxiliary amplifier branch 305 between the second output port 322 of the IPS 301 and an input end 326 of the auxiliary amplifier, the output end of the auxiliary amplifier being connected to the common node 307. The NDA is biased in deep class C bias condition. It is important that the NDA is non linear and biased in class C, which means that the NDA will only be in operation above a turn on point when the Doherty power region is entered. This has the effect that for the low power region when only the main amplifier branch is in operation the efficiency of the power amplifier of the invention is the same as the efficiency of a standard Doherty amplifier as shown in FIG. 8. Conversely, if a linear gain stage biased in class AB was used, it would have consumed DC-power also in the lower power region, thus decreasing the efficiency.

The NDA is arranged in order to increase the power gain in the power amplifier and consequently also to improve the PAE.

The main amplifier is preferably operating in a class AB bias condition and the auxiliary amplifier is preferably operating in a class B or C bias condition.

The invention is further based on that a Phase Compensation Network, PCN, 310 is arranged in the main amplifier branch 302 between the first output port 321 of the IPS 301 and an input end 327 of the main amplifier, the output end 325 of the main amplifier 303 being connected to the IIN input port 328, the IIN output port 329 being connected to the common node 307.

The basic topology of FIG. 3 also includes an alternative with a possible integration of the IPS and the PCN as will be described.

The PCN is arranged to adjust the phase of the main input power signal P1 in the main amplifier branch 302 to be in phase with the auxiliary input power signal P2 in the auxiliary amplifier branch 305 at the common node 307 and the NDA 309 is, as mentioned, arranged to increase the gain in the auxiliary amplifier branch 305. In the main amplifier branch the main amplifier phase shifts 180 degrees with reference to the input port 320 of the IPS. The IIN adds a further phase shift, in most applications substantially 90 degrees. Other phase shifts are possible as will be described in association with FIG. 5. The auxiliary amplifier in the auxiliary amplifier branch phase shifts 180 degrees with respect to the input port 320 of the IPS, while the NDA introduce a further phase shift of 180 degrees from the second output port 322 of the IPS to the input end of the auxiliary amplifier 306. Thus the PCN in the main amplifier branch must phase shift with the same amount as the IIN (in the case when IIN phase shifts with 90 degrees, in the general case the sum of the IIN and PCN phase shifts should be equal to the phase shift of the NDA) in order for the main input power signal P1 travelling in the main amplifier branch and the auxiliary input power signal P2 travelling in the auxiliary amplifier branch to be in phase at the common node 307.

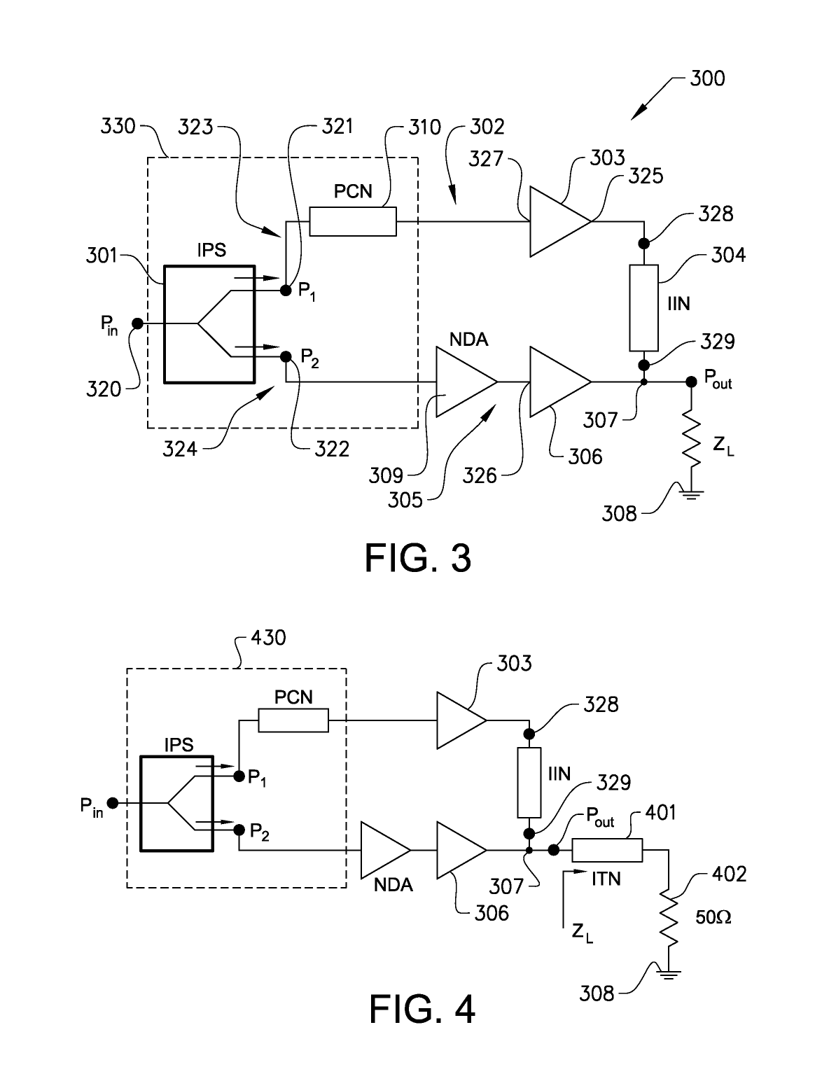

To accomplish a standard 50 ohm termination in practical realizations, usually an Impedance Transforming Network, ITN, 401 is arranged in series with the 50 ohm termination 402 between the common node 307 and a first end of the 50 ohm termination, the second end of which is connected to the ground 308. This is illustrated in FIG. 4, otherwise having the same topology as FIG. 3. The load Z_{L} thus comprises the Impedance Transforming Network, ITN, in series with a 50 ohm termination and the ITN is arranged to transform the 50 ohm to Z_{L}.

The relation between the main input power signal P1 and the auxiliary input power signal P2 in the power amplifier of the invention is greater than 1 at the output ports of the IPS, i.e. the main input power signal P1 is greater than the auxiliary input power signal P2 at the output ports of the IPS. This has the effect to increase the contribution of the main amplifier gain on the overall gain of the new power amplifier, while reducing the contribution of the auxiliary amplifier branch, thus allowing to reach a gain level similar to the one obtainable with a simple combination of two identical amplifiers as shown in FIG. 2.

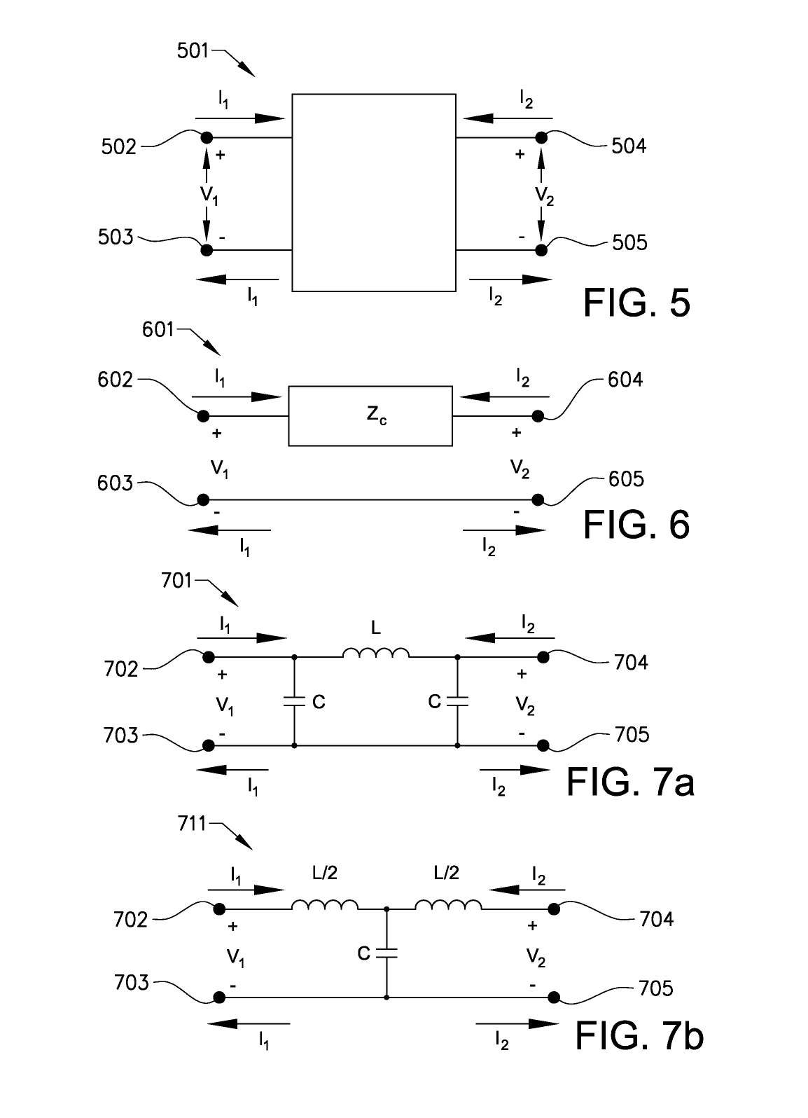

For realization of both the main and the auxiliary amplifiers any suitable type of semiconductor and active device (i.e. bipolar or field effect based) can be used. The overall structure of the power amplifier can be implemented both in hybrid (MIC, Microwave Integrated Circuit) or monolithic (MMIC, Monolithic Microwave Integrated Circuit) technology. The components as such included in the topology of the new power amplifier can be designed for operation within one or several frequency ranges as is well known to the skilled person. Both the main amplifier and the auxiliary amplifier, as well as the other components of the power amplifier, can thus be arranged to operate within at least one frequency range, each frequency range defining a bandwidth with a centre frequency, thus allowing the power amplifier to be arranged to operate within at least one frequency range, each frequency range defining a bandwidth with a centre frequency. In FIGS. 6-7 some examples of realizations within one frequency range is shown. The design relationships of the IIN to operate within several frequency ranges can e.g. be found in, “A Stub Tapped Branch-Line Coupler for Dual-Band Operations”, IEEE Microwave and Wireless Components Letters, Vol. 17, No. 2, February 2007 by H. Zhang and K. J. Chen. The amplifiers in the new power amplifier can be of any suitable type for the intended application and building technology.

The IIN can be accomplished in many ways as is well known to the skilled person. In general terms the IIN can be defined as is illustrated in FIG. 5 where the IIN comprises a 4-port device 501 with an input plus port 502 and an input minus port 503 and with an output plus port 504 and an output minus port 505. A first current I₁ is arranged to flow into the IIN at the input plus port 502 and an equal second current I₁ is arranged to flow out of the IIN at the input minus port. A third current I₂ is arranged to flow into the IIN at the output plus port 504 and an equal fourth current I₂ is arranged to flow out of the IIN at the output minus port 505. The minus ports are connected to the ground. A first voltage between the input ports is arranged to be V₁ and a second voltage between the output ports is arranged to be V₂. The IIN further comprises a single or multiple, passive or active, component/s arranged to satisfy:

$$( \begin{matrix}{V}_{2} \\ {I}_{2}\end{matrix} ) = [ \begin{matrix}A & B \\ C & D\end{matrix} ] \cdot ( \begin{matrix}{V}_{1} \\ {I}_{1}\end{matrix} ) \qquad ( 1 )$$

where the elements A, B, C and D in a transmission matrix are complex values calculated for each centre frequency for each element.

$$( \begin{matrix}{V}_{2} \\ {I}_{1}\end{matrix} ) and ( \begin{matrix}{V}_{1} \\ {I}_{1}\end{matrix} )$$

are column vectors. When the power amplifier is operating within several frequency ranges the element A assumes the same value at each centre frequency. Similarly the other elements also assume the same value at each centre frequency, however each of the elements have individual and, mostly, different values.

The IIN input and output ports correspond to the input and output plus ports of FIG. 5.

The transmission matrix above accounts for the losses of the passive elements adopted for the implementation of the IIN. Assuming passive and lossless elements for the implementation of the IIN, the relationship between the currents and voltages across the IIN network can be represented with the transmission matrix as follows:

$$( \begin{matrix}{V}_{2} \\ {I}_{2}\end{matrix} ) = [ \begin{matrix}0 & B \\ C & 0\end{matrix} ] \cdot ( \begin{matrix}{V}_{1} \\ {I}_{1}\end{matrix} ) \qquad ( 2 )$$

In equation (2) the elements A and D are equal to zero and the elements B and C are two constant purely imaginary values at each centre frequency. The effectiveness of the adopted topology for the implementation of the IIN depends on how much equation (1) approaches equation (2).

The phase shift of the IIN depends on the values of the elements B and C. Typically the phase shift is substantially 90 degrees at the centre frequency/ies for most of the practical implementations of the invention, which means that for typical realizations the IIN inverts the impedance, hence the name IIN. If the phase shift of the IIN is not exactly 90°, then a complex transformation is performed by the IIN, i.e. a purely resistive load at the output ports (504/505) is transformed into a complex impedance seen at the input ports (502/503). In this case, the main amplifier of the power amplifier will operate in a sub-optimum condition, i.e. with a complex load instead of a purely resistive load. Consequently, less active output power will be delivered from the main amplifier, and a power loss in both AC and DC power is introduced by a dissipation in the main amplifier due to a partial overlap between voltage and current waveforms across the main amplifier, thus resulting in reducing the performance achievable by the main amplifier. The phase shift should thus ideally be 90° at the centre frequency/ies. The invention can however also be implemented with somewhat degraded performance for phase shifts being substantially 90° at the centre frequency/ies, here defined as being within a range of ±30% from 90°, preferably within ±15% but most preferably within ±10%. The phase shift can also be odd multiples of 90°, this has however the drawback of increasing the size of the IIN and further to introduce losses and reduce power amplifier performance. These ranges are valid for all examples and embodiments of the invention.

In case of adopting active components for the implementation of the IIN, the values of the elements B and C in (1) and (2) can be real.

There are several possibilities to realize the IIN using passive elements. FIG. 6 shows an IIN 601 for a power amplifier operating within a bandwidth B with a centre frequency f₀. The most adopted and well-known solution is the adoption of a distributed lambda quarter transmission line, as shown in FIG. 6. This means that the transmission line is characterized by an electrical length of substantially 90° at the centre frequency f₀ and has a characteristic impedance Z_{C}. The IIN comprises an input plus port 602, an input minus port 603, an output plus port 604 and an output minus port 605. A first voltage between the input ports is arranged to be V₁ and a second voltage between the output ports is arranged to be V₂. A first current I₁ is flowing into the IIN from the input plus port 602 and an equal second current I₁ is coming out from the input minus port 603, while a third current I₂ is flowing into the IIN from the output plus port 604 and an equal fourth current I₂ is coming out from the output minus port 605. The minus ports are connected to the ground. The transmission line is realized between the input ports 602/603 and the output ports 604/605. It means that in this example the IIN 601 comprises a transmission line with an electrical length of substantially 90° at the centre frequency f₀ corresponding to an electrical length of substantially a quarter of the wavelength at the centre frequency f₀ and a characteristic impedance Zc arranged to satisfy the transmission matrix:

$$A B C D = [ \begin{matrix}0 & j \cdot {Z}_{C} \\ \frac{j}{{Z}_{C}} & 0\end{matrix} ]$$

The lambda quarter solution of the IIN can also be implemented by using its equivalent lumped implementation, thus accomplishing an equivalent transmission line. The two networks typically adopted are shown in FIGS. 7a and 7b, based on the use of capacitances C and inductances L.

FIGS. 7a and 7b shows examples of Impedance Inverter Networks, IINs for a power amplifier operating within a bandwidth B with a centre frequency f₀ where, in FIG. 7a, the IIN 701 comprises an equivalent transmission line with a capacitance C across both the input ports, 702/703, and the output ports, 704/705, and with an inductance L between the input plus port 702 and output plus port 704. In both FIGS. 7a and 7b the minus ports are connected to the ground. In FIG. 7b, the IIN 711 comprises an equivalent transmission line with an inductance L between the input plus port 702 and output plus port 704 and with a capacitance C from a midpoint of the inductance L to the ground, the input and output minus ports in both configurations being connected to the ground. In both networks, according to FIGS. 7a and 7b, a first voltage between the input ports, 702/703 is arranged to be V₁ and a second voltage between the output ports, 704/705 is arranged to be V₂. A first current I₁ is flowing into the IIN from the input plus port 702 and an equal second current I₁ is coming out from the input minus port 703, while a third current I₂ is flowing into the IIN from the output plus port 704 and an equal fourth current I₂ is coming out from the output minus port 705. The inductance and capacitances are arranged to satisfy:

$${f}_{0} = \frac{1}{2 π \cdot \sqrt{L \cdot C}}$$

$$and$$

$${Z}_{C} = \sqrt{\frac{L}{C}}$$

where f₀ is the centre frequency and Zc the characteristic impedance of the equivalent transmission line, resulting in a transmission matrix:

$$A B C D = [ \begin{matrix}0 & j \cdot \sqrt{\frac{L}{C}} \\ j \cdot \sqrt{\frac{C}{L}} & 0\end{matrix} ] .$$

These two standard approaches can be modified in several ways in order to optimize for certain circuit implementation.

In FIG. 7a the two capacitances shall normally have the same value and the capacitance value of one of the capacitors and the value of the inductance shall be used in the formulas for f₀ and Zc.

In FIG. 7b the total value of the inductance between the input and output plus ports and the capacitance value of the capacitor shall be used in the formulas for f₀ and Zc. In general every topology or circuit network, active, passive or both, having an ABCD matrix of the form reported in equation (1) and (2), can be adopted for the implementation of the IIN.

The IIN input and output ports correspond to the input and output plus ports of FIGS. 6 and 7.

The currents and voltages in equation (1) and (2) and the currents (except in the explanation of the abbreviations AC and DC) and voltages mentioned in the description, claims and figures are, unless otherwise stated, the alternating voltage and alternating current at the centre frequency in the frequency range in question.

Expressions defining amounts of power or power signals such as e.g. input power, output power, power output, input power signal Pin, output power signal Pout, main input power signal P1, auxiliary input power signal P2, first input power signal P1 and second input power signal P2, mentioned in the description and claims concern AC (Alternating Current) power or AC signals at the centre frequency in the frequency range in question, unless otherwise stated. General terms like e.g. power, power splitter, Input Power Splitter, power combiner, power gain, power amplification and power amplifier also concerns AC power unless otherwise stated.

The ITN can be realized as an IIN or as any network performing a load transformation from 50 ohm to Z_{L}. The most typical solutions are based on networks similar to the ones adopted for the IIN structure, and in particular the distributed lambda quarter transmission line shown in FIG. 6.

Similarly, the PCN network can be realized as an IIN with one of the possible solutions described for the IIN.

The IPS can be realized with any kind of power splitter structure as a T-junction, a resistive divider or as a Wilkinson type of power splitter.

The IPS and PCN can be integrated in a single structure by using 90° hybrid structures, realized as branch line, coupled lines or any other solution well known to the skilled person. These hybrid structures 330/430 are schematically shown in FIGS. 3 and 4.

FIGS. 8a and 8b shows, as mentioned earlier, an example of performance behaviour of the new power amplifier and a standard DPA, in terms of gain, efficiency and PAE.

FIG. 8a shows the gain in dB on the y-axis 802 as a function of the OBO on the x-axis 801 for the power amplifier with graph 804 and a standard DPA with graph 805. The gain of the power amplifier of the invention is in this example about 5 dB above the gain of the standard DPA (2 dB between each division). The OBO is in dB below a maximum power output of the power amplifier being equal to a maximum output power signal Pout over the load Z_{L}.

FIG. 8b shows the efficiency and PAE in percentage on the y-axis 803 as a function of the OBO on the x-axis 801. Graph 807 shows the PAE of the invention and graph 806 the PAE of the standard DPA. As can be seen the PAE of the power amplifier of the invention is above the PAE of the DPA, especially around an efficiency peak, called the first efficiency peak, at around OBO 7.5 dB, where the PAE difference in this example is almost 20% (20% between each division). Graph 808 shows the efficiency of the power amplifier of the invention and graph 809 the efficiency of the standard DPA. As can be seen these two graphs coincide below the first efficiency peak, i.e. for output back offs, OBOs, greater than the OBO at the first efficiency peak. Above the first efficiency peak, i.e. for OBOs less than the OBO at the first efficiency peak, the efficiency of the standard DPA is slightly above the efficiency of the power amplifier of the invention, in this example with about 5-10%.

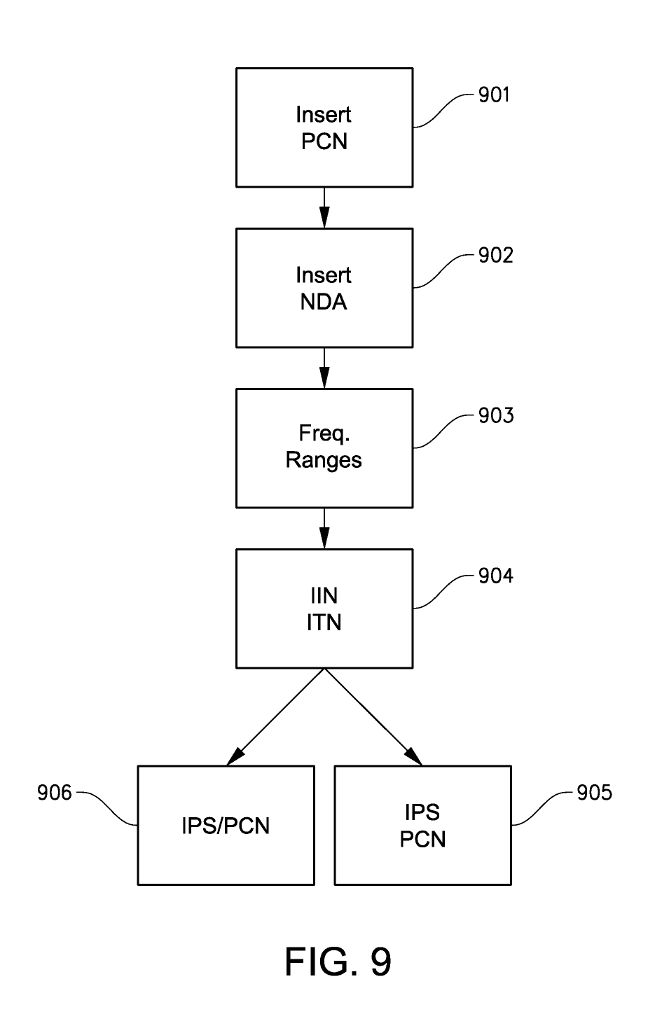

The invention also provides a method for power amplification which is illustrated in the block diagram of FIG. 9. The method is based on the power amplifier of claim 1 which in turn is based on an evolution of the DPA as described. One example of the method of the invention is described in the following five method steps.

In a first method step a Phase Compensation Network, PCN, is inserted 901 in the main amplifier branch 302 between the first output port 321 of the IPS 301 and an input end 327 of the main amplifier. The output end 325 of the main amplifier 303 is connected to the IIN input port 328, the IIN output port 329 being connected to the common node 307. The PCN is adjusting the phase of the main input power signal P1 in the main amplifier branch 302 to be in phase with the auxiliary input power signal P2 in the auxiliary amplifier branch 305 at the common node 307.

In a second method step a Nonlinear Driver Amplifier, NDA, 309 is inserted 902 in the auxiliary amplifier branch 305 between the second output port 322 of the IPS 301 and an input end 326 of the auxiliary amplifier. The output end of the auxiliary amplifier is connected to the common node 307. The NDA increases the gain in the auxiliary amplifier branch 305.

In a third method step the numbers of frequency ranges are selected, 903, for the actual application.

In a fourth method step the IIN is selected to be realized, 904, according to anyone of claims 4-6 and an ITN according to claim 3 is realized, 904, as an IIN.

In a fifth method step:
the IPS is realized, 905, with a power splitter structure as a T-junction, a resistive divider or as a Wilkinson type of power splitter and the PCN is realized, 905, as an IIN or
the IPS and the PCN are integrated, 906, in a single structure by using a 90° hybrid structure.

The different method steps do not necessarily have to be performed in the order described above. As an example, step 2 can be performed before step 1 and step 4 before step 3.

In summary the invention also provides a method for power amplification where an input port of a three port Input Power Splitter, IPS, 301 receives an input power signal Pin. The IPS also has a first 321 and a second 322 output port. The IPS delivers a main input power signal P1 at the first output port to an input end 323 of a main amplifier branch 302 having a main amplifier 303 coupled in series with an Impedance Inverter Network, IIN 304, having an IIN input port 328 and an IIN output port 329, and an auxiliary input power signal P2 at the second output port 322 to an input end 324 of an auxiliary amplifier branch 305 with an auxiliary amplifier 306. An output end 325 of the main amplifier 303 is connected to an output end of the auxiliary amplifier branch 305 via the IIN 304. The output end of the auxiliary amplifier branch 305 defines a common node 307. The power amplifier delivers an output power signal Pout to the common node 307 wherein the power amplifier is operating within at least one frequency range, each frequency range defining a bandwidth with a centre frequency and wherein a Phase Compensation Network, PCN, 310 is inserted, 901, in the main amplifier branch 302 between the first output port 321 of the IPS 301 and an input end 327 of the main amplifier. The output end 325 of the main amplifier 303 is connected to the IIN input port 328, the IIN output port 329 being connected to the common node 307 and wherein further a Nonlinear Driver Amplifier, NDA, 309 is inserted, 902, in the auxiliary amplifier branch 305 between the second output port 322 of the IPS 301 and an input end 326 of the auxiliary amplifier. The output end of the auxiliary amplifier is connected to the common node 307. The PCN 310 adjusts the phase of the main input power signal P1 in the main amplifier branch 302 to be in phase with the auxiliary input power signal P2 in the auxiliary amplifier branch 305 at the common node 307 and the NDA 309 increases the gain in the auxiliary amplifier branch 305.

In one example of the method the number of frequency ranges are selected, 903, for the actual application.

In one example of the method the IIN is selected to be realized, 904, according to anyone of claims 4-6 and an ITN according to claim 3 is realized, 904, as an IIN.

In one example of the method:
the IPS is realized, 905, with a power splitter structure as a T-junction, a resistive divider or as a Wilkinson type of power splitter and the PCN is realized, 905, as an IIN or
the IPS and the PCN are integrated, 906, in a single structure by using a 90° hybrid structure.

The invention also provides a node in a wireless communication system, wherein the node comprises a power amplifier according to any one of claims 1-10. The wireless communication system can e.g. be based on 3G (Third generation mobile telecommunication), 4G (Fourth generation mobile telecommunication), LTE (Long term evolution) or WiMax (Worldwide interoperability for microwave access). The invention is however not restricted to a certain type of wireless communication system but can also be used in any other wireless communication applications or electronic systems requiring power amplification.

The invention is not limited to the embodiments and examples described above, but may vary freely within the scope of the appended claims.

1. A power amplifier configured to receive an input power signal (Pin) at an input port of a three port Input Power Splitter, IPS, comprising a first and a second output port, the IPS being configured to deliver a main input power signal (P1) at the first output port to an input end of a main amplifier branch comprising a main amplifier coupled in series with an Impedance Inverter Network, IIN, having an IIN input port and an IIN output port, and an auxiliary input power signal (P2) at the second output port to an input end of an auxiliary amplifier branch comprising an auxiliary amplifier, an output end of the main amplifier being connected to an output end of the auxiliary amplifier branch via the IIN, the output end of the auxiliary amplifier branch defining a common node, the power amplifier being configured to deliver an output power signal (Pout) to the common node, wherein the power amplifier is further configured to operate within at least one frequency range, said at least one frequency range defining a bandwidth with a center frequency, and a Phase Compensation Network, PCN, positioned in the main amplifier branch between the first output port of the IPS and an input end of the main amplifier, the output end of the main amplifier being connected to the IIN input port, the IIN output port being connected to the common node, and a Nonlinear Driver Amplifier, NDA, positioned in the auxiliary amplifier branch between the second output port of the IPS and an input end of the auxiliary amplifier, the output end of the auxiliary amplifier being connected to the common node, the PCN being configured to adjust the phase of the main input power signal (P1) in the main amplifier branch to be in phase with the auxiliary input power signal (P2) in the auxiliary amplifier branch at the common node and the NDA being configured to be biased in class C and to increase the gain in the auxiliary amplifier branch.

2. A power amplifier according to claim 1, wherein the power amplifier is further configured to deliver the output power signal (Pout) to a load Z_{L} connected to the power amplifier and includes a first end and a second end, the first end being connected to the common node and the second end to a ground.

3. A power amplifier according to claim 2, wherein the load Z_{L} comprises an Impedance Transforming Network, ITN, in series with a 50 ohm termination, the ITN being configured to transform the 50 ohm to Z_{L}.

4. A power amplifier according to claim 1, wherein the IIN comprises a 4-port device with an input plus port and an input minus port, and an output plus port and an output minus port, a first current I₁ arranged to flow into the IIN at the input plus port and an equal second current I₁ arranged to flow out of the IIN at the input minus port, a third current I₂ arranged to flow into the IIN at the output plus port and an equal fourth current I₂ arranged to flow out of the IIN at the output minus port, the minus ports being connected to the ground and a first voltage between the input ports is arranged to be V₁ and a second voltage between the output ports is arranged to be V₂, and the IIN further comprises a single or multiple, passive or active, component/s arranged to satisfy:
$$( \begin{matrix}{V}_{2} \\ {I}_{2}\end{matrix} ) = [ \begin{matrix}A & B \\ C & D\end{matrix} ] \cdot ( \begin{matrix}{V}_{1} \\ {I}_{1}\end{matrix} )$$
where the elements A, B, C and D in a transmission matrix are complex values calculated for each center frequency for each element.

5. A power amplifier according to claim 4, wherein the power amplifier is operating within a bandwidth B with a center frequency f₀ and the IIN comprises a transmission line with an electrical length of substantially a quarter of the wavelength at the center frequency f₀ and a characteristic impedance Zc arranged to satisfy the transmission matrix:
$$A B C D = [ \begin{matrix}0 & j \cdot {Z}_{C} \\ \frac{j}{{Z}_{C}} & 0\end{matrix} ] .$$

6. A power amplifier according to claim 4, wherein the power amplifier is operating within a bandwidth B with a center frequency f₀ and the IIN comprises an equivalent transmission line with a capacitance C across both the input ports and the output ports and with an inductance L between the input plus port and output plus port or the IIN comprises an equivalent transmission line with an inductance L between the input plus port and the output plus port and with a capacitance C from a midpoint of the inductance L to the ground, the input and output minus ports in both configurations being connected to the ground, wherein the inductance and capacitances are arranged to satisfy:
$${f}_{0} = \frac{1}{2 π \cdot \sqrt{L \cdot C}} and {Z}_{C} = \sqrt{\frac{L}{C}}$$
where f₀ is the frequency and Zc the characteristic impedance of the equivalent transmission line, resulting in a transmission matrix:
$$A B C D = [ \begin{matrix}0 & j \cdot \sqrt{\frac{L}{C}} \\ j \cdot \sqrt{\frac{C}{L}} & 0\end{matrix} ] .$$

7. A power amplifier according to claim 3, wherein the ITN is configured as an IIN.

8. A power amplifier according to claim 1, wherein the PCN is configured as an IIN.

9. A power amplifier according to claim 1, wherein the IPS is configured with a power splitter structure as a T-junction, a resistive divider or as a Wilkinson type of power splitter.

10. A power amplifier according to, claim 1, wherein the IPS and the PCN are integrated in a single structure by using a 90° hybrid structure.

11. A method for power amplification comprising: an input port of a three port Input Power Splitter, IPS, receiving an input power signal (Pin), the IPS comprising a first and a second output port; the IPS delivering a main input power signal (P1) at the first output port to an input end of a main amplifier branch comprising a main amplifier coupled in series with an Impedance Inverter Network, IIN, comprising an IIN input port and an IIN output port, and an auxiliary input power signal (P2) at the second output port to an input end of an auxiliary amplifier branch with an auxiliary amplifier, an output end of the main amplifier being connected to an output end of the auxiliary amplifier branch via the IIN, the output end of the auxiliary amplifier branch defining a common node, the power amplifier delivering an output power signal (Pout) to the common node wherein the power amplifier is operating within at least one frequency range, said at least one frequency range defining a bandwidth with a center frequency, and wherein a Phase Compensation Network, PCN, is inserted in the main amplifier branch between the first output port of the IPS and an input end of the main amplifier, the output end of the main amplifier being connected to the IIN input port, the IIN output port being connected to the common node, and a Nonlinear Driver Amplifier, NDA, is biased in class C and inserted in the auxiliary amplifier branch between the second output port of the IPS and an input end of the auxiliary amplifier, the output end of the auxiliary amplifier being connected to the common node, the PCN adjusting the phase of the main input power signal (P1) in the main amplifier branch to be in phase with the auxiliary input power signal (P2) in the auxiliary amplifier branch at the common node and the NDA increasing the gain in the auxiliary amplifier branch.

12. A method according to claim 11, wherein the number of frequency ranges are selected for the actual application.

13. A method according to claim 11, wherein the IIN comprises a 4-port device with an input plus port and an input minus port, and an output plus port and an output minus port, a first current I₁ arranged to flow into the IIN at the input plus port and an equal second current I₁ arranged to flow out of the IIN at the input minus port, a third current I₂ arranged to flow into the IIN at the output plus port and an equal fourth current I₂ arranged to flow out of the MN at the output minus port, the minus ports being connected to the ground and a first voltage between the input ports is arranged to be V₁ and a second voltage between the output ports is arranged to be V₂, and the IIN further comprises a single or multiple, passive or active, component/s arranged to satisfy:
$$( \begin{matrix}{V}_{2} \\ {I}_{2}\end{matrix} ) = [ \begin{matrix}A & B \\ C & D\end{matrix} ] \cdot ( \begin{matrix}{V}_{1} \\ {I}_{1}\end{matrix} )$$
where the elements A, B, C and D in a transmission matrix are complex values calculated for each center frequency for each element, and wherein an Impedance Transforming Network, ITN, in series with a 50 ohm termination is configured as an IIN.

14. A method according to, claim 11, wherein:
the IPS is configured with a power splitter structure as a T-junction, a resistive divider or as a Wilkinson type of power splitter and the PCN is configured as an IIN or
the IPS and the PCN are integrated in a single structure by using a 90° hybrid structure.

15. A node in a wireless communication system, wherein the node comprises a power amplifier configured to receive an input power signal (Pin) at an input port of a three port Input Power Splitter, IPS, comprising a first and a second output port, the IPS being configured to deliver a main input power signal (P1) at the first output port to an input end of a main amplifier branch comprising a main amplifier coupled in series with an Impedance Inverter Network, IIN, having an IIN input port and an IIN output port, and an auxiliary input power signal (P2) at the second output port to an input end of an auxiliary amplifier branch comprising an auxiliary amplifier, an output end of the main amplifier being connected to an output end of the auxiliary amplifier branch via the IIN, the output end of the auxiliary amplifier branch defining a common node, the power amplifier being configured to deliver an output power signal (Pout) to the common node, wherein the power amplifier is further configured to operate within at least one frequency range, said at least one frequency range defining a bandwidth with a center frequency, and a Phase Compensation Network, PCN, positioned in the main amplifier branch between the first output port of the IPS and an input end of the main amplifier, the output end of the main amplifier being connected to the IIN input port, the IIN output port being connected to the common node, and a Nonlinear Driver Amplifier, NDA, positioned in the auxiliary amplifier branch between the second output port of the IPS and an input end of the auxiliary amplifier, the output end of the auxiliary amplifier being connected to the common node, the PCN being configured to adjust the phase of the main input power signal (P1) in the main amplifier branch to be in phase with the auxiliary input power signal (P2) in the auxiliary amplifier branch at the common node and the NDA being configured to be biased in class C and to increase the gain in the auxiliary amplifier branch.
